(19) United States
(12) Patent Application Publication
(10) Pub. No.: US 2024/0379479 A1
(43) Pub. Date: Nov. 14, 2024

(54) Semiconductor Device and Method of Making a Fan-Out Semiconductor Package with Pre-Assembled Passive Modules

(71) Applicant: STATS ChipPAC Pte. Ltd., Singapore (SG)

(72) Inventors: Yaojian Lin, Jiangyin (CN); Linda Pei Ee Chua, Singapore (SG); Ching Meng Fang, Singapore (SG); Hin Hwa Goh, Singapore (SG)

(73) Assignee: STATS ChipPAC Pte. Ltd., Singapore (SG)

(21) Appl. No.: 18/315,098

(22) Filed: May 10, 2023

(51) Int. Cl. H01L 23/31; H01L 21/56; H01L 23/00; H01L 25/00; H01L 25/16

(52) U.S. Cl. CPC H01L 23/3135; H01L 21/56; H01L 24/19; H01L 24/20; H01L 25/165; H01L 25/50; H01L 2224/19; H01L 2224/21

(57) ABSTRACT

A semiconductor device includes a plurality of electrical components. A first encapsulant is deposited over the plurality of electrical components to form a module. The module is disposed adjacent to a semiconductor die. A second encapsulant is deposited over the semiconductor die and module. A build-up interconnect structure is formed over the second encapsulant, module, and semiconductor die.

### FIELD OF THE INVENTION

The present invention relates in general to semiconductor devices and, more particularly, to a semiconductor device and method of making a fan-out semiconductor package with pre-assembled passive modules.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices may contain multiple electrical components, e.g., one or more semiconductor die and myriad discrete components to support the semiconductor die, disposed on one or more substrates to perform necessary electrical functions. FIGS. 1a-1d illustrate forming such fan-out SiP semiconductor packages 50. In FIG. 1a, semiconductor die 54 and discrete components 56 are disposed on a carrier 60. Terminals 58 of components 56 lie flat on the carrier in predetermined locations so that conductive layers can be formed contacting the terminals in subsequent manufacturing steps. Carrier 60 commonly has an adhesive layer 61 or other interface layer to help the components stay in place.

In FIG. 1b, an encapsulant or molding compound 62 is deposited over the components to form a panel of devices. Encapsulant 62 is deposited into a mold or using another method that involves the encapsulant material flowing over, around, and under the semiconductor die 54 and discrete components 56.

One common issue in the prior art, illustrated in FIG. 1b, is that the encapsulant applying physical pressure against components tends to move the components. Discrete component 56a in FIG. 1b has been moved by the force of encapsulant 62 to such an extent that terminal 58a is lifted off carrier 60 and terminal 58b is now laterally offset from its intended position. The movement of component 56 causing a defect is referred to as a flying or floating component.

In FIG. 1c, the panel of devices is flipped with carrier 60 removed for the formation of a build-up interconnect structure 70 over the panel for external interconnect. The panel is singulated in FIG. 1d to complete semiconductor packages 50. Due to the movement of component 56a during encapsulation, package 50a has a defect that renders the package unusable. Component 56a is not electrically coupled to build-up interconnect structure 70 as intended. The electrical functionality of package 50a will be degraded or completely broken.

The above-described problem is common in the prior art. Accordingly, a need exists for an improved fan-out package and method of making.

### BRIEF DESCRIPTION OF THE DRAWINGS

FIG. 1a-1d illustrate a manufacturing defect when forming a fan-out semiconductor package;

FIGS. 2a-2c illustrate a semiconductor wafer with a plurality of semiconductor die separated by a saw street;

FIGS. 3a-3k illustrate forming pre-assembled passive modules;

FIGS. 4a-4e illustrate forming fan-out semiconductor packages with the pre-assembled passive modules;

FIGS. 5a-5c illustrate forming pre-assembled passive modules with an embedded interconnect substrate;

FIGS. 6a-6h illustrate forming a pre-assembled passive module with leadframe technology;

FIGS. 7a-7d illustrate forming a fan-out semiconductor package with the pre-assembled passive modules and wettable flanks at the edges of the package;

FIG. 8 illustrates an additional wettable flank embodiment;

FIGS. 9a-9d illustrate forming wettable flanks using leadframe technology;

FIGS. 10a-10c illustrate pre-assembled passive modules with additional types of components; and

FIGS. 11a and 11b illustrate an electronic device with the fan-out semiconductor packages.

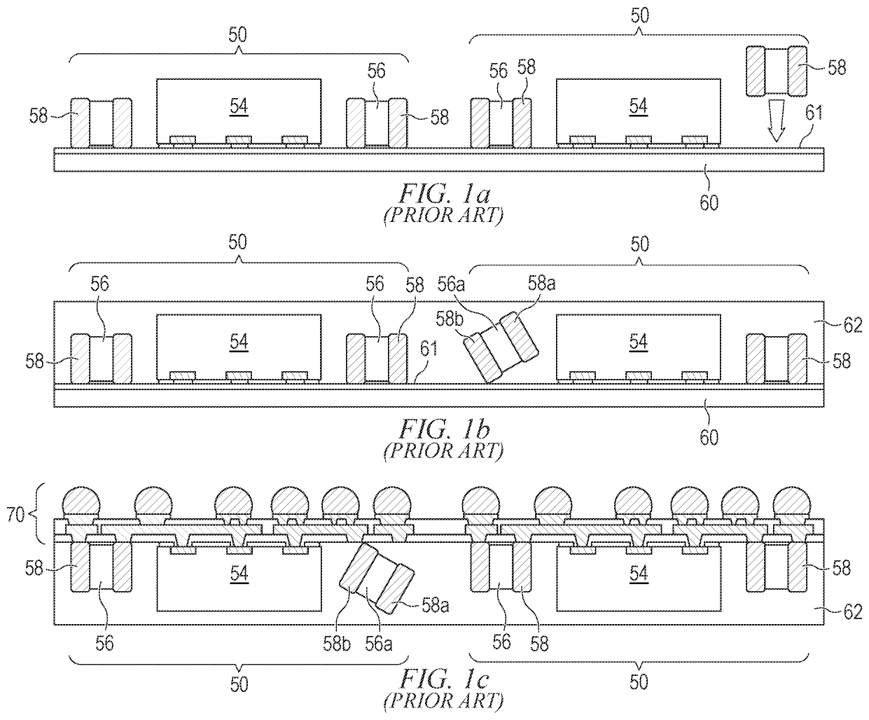

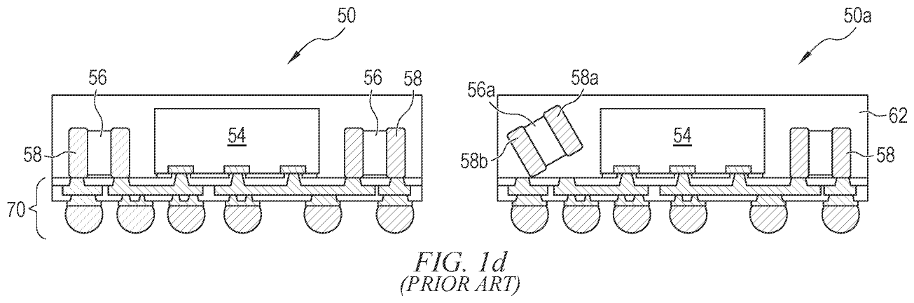

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

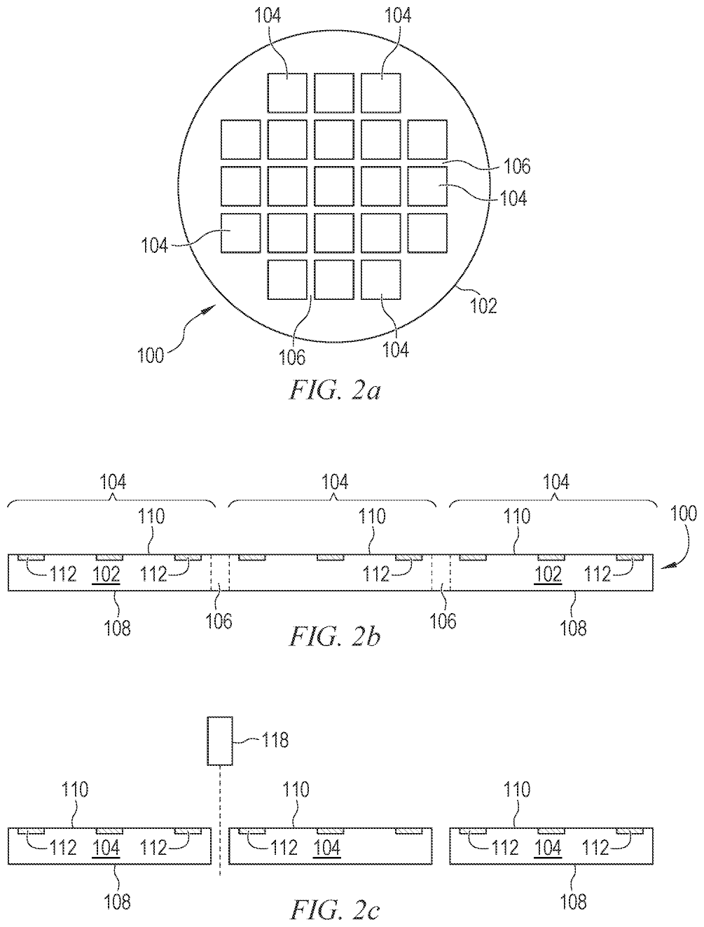

FIG. 2a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 2b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 2c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

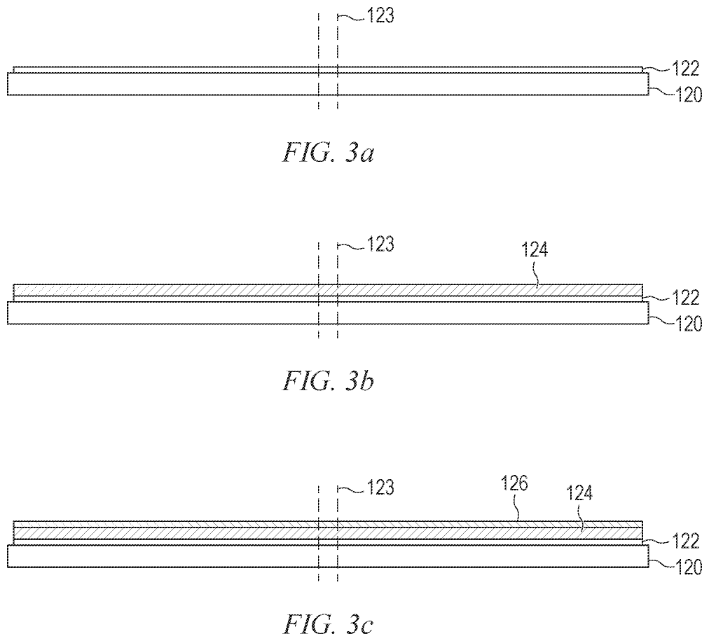

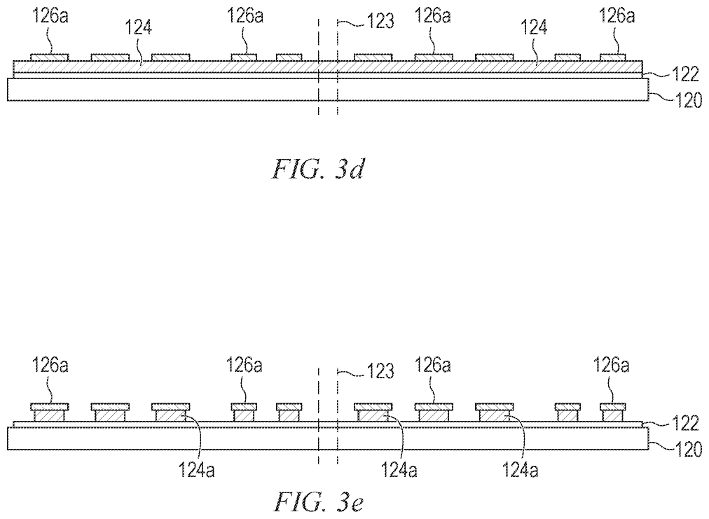

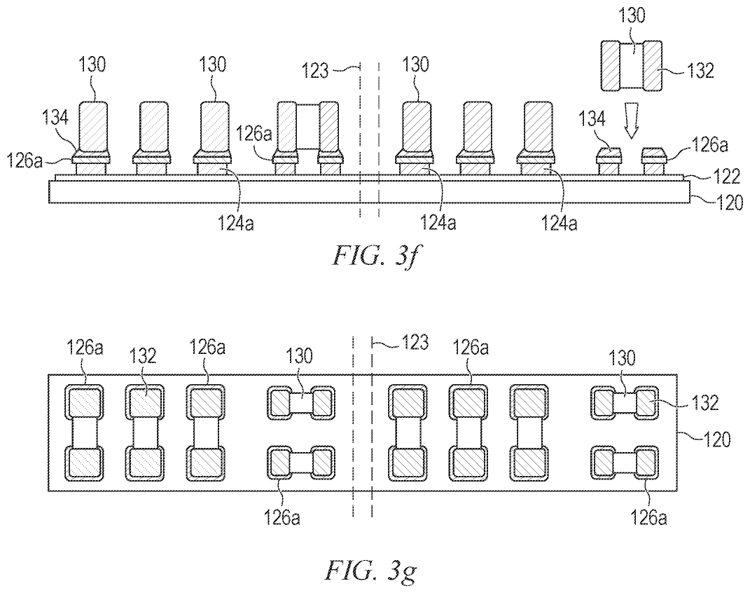

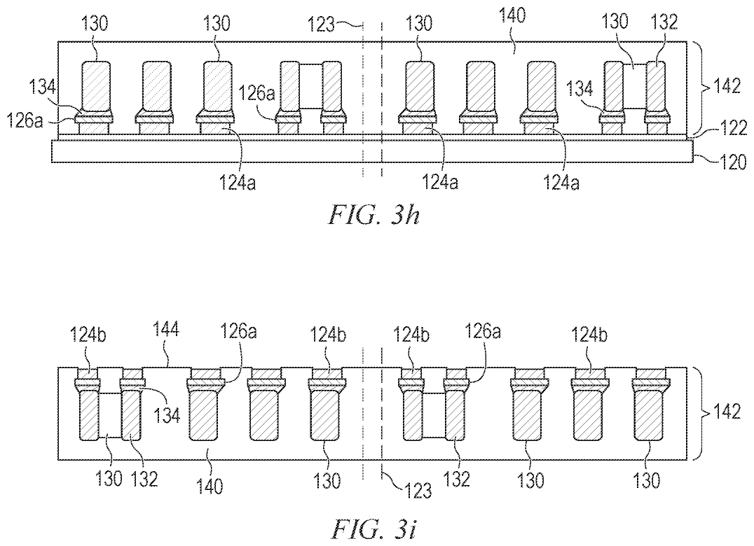

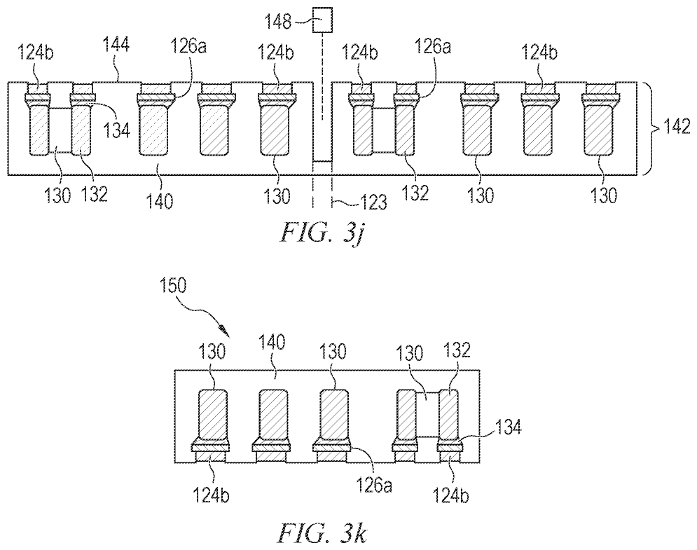

FIGS. 3a-3k illustrate a process of forming pre-assembled passive modules. The term “passive modules” is used because passive electrical components, e.g., resistors, capacitors, inductors, etc., are most commonly used. However, discrete active components, such as transistors and diodes, as well as semiconductor die with integrated circuits, can also be placed within the passive modules even though those components are not generally considered passive. The term “pre-assembled passive modules” is intended as a name and not necessarily an accurate description of all embodiments.

FIG. 3a shows a cross-sectional view of a portion of a carrier or temporary substrate 120 containing sacrificial base material such as silicon, polymer, beryllium oxide, glass, or other suitable low-cost, rigid material for structural support. An interface layer or double-sided tape 122 is formed or disposed over carrier 120 as a temporary adhesive bonding film, etch-stop layer, thermal release layer, or UV release layer. Carrier 120 can be a round or rectangular panel with capacity for multiple passive modules to be formed at once with saw streets 123 between each unit. While only two units are illustrated being formed, hundreds or more modules may be formed together on a common carrier.

In FIG. 3b, a first electrically conductive layer 124 is formed over carrier 120 using a metal deposition process such as printing, PVD, CVD, sputtering, electrolytic plating, or electroless plating. Conductive layer 124 includes one or more layers of Al, Cu, Sn, Ni, Au, Ag, or other suitable electrically conductive material. In FIG. 3c, a second conductive layer 126 is formed over conductive layer 124. Conductive layer 126 is formed using a similar process and a similar material as those listed for conductive layer 124, although the two layers are formed of different materials from each other in many embodiments. In one example, conductive layer 124 is formed of copper and conductive layer 126 is formed of nickel. In some embodiments, conductive layer 124 is a pre-formed sheet or film of copper laminated over carrier 120, and conductive layer 126 is a nickel layer plated onto conductive layer 124. Both conductive layers 124 and 126 completely or substantially cover a footprint of carrier 120.

In FIG. 3d, second conductive layer 126 is patterned to form contact pads 126a for electrical components to be mounted to. In some embodiments, portions of conductive layer 126 remain as conductive traces electrically coupling contact pads 126a to each other as desired for the intended electrical function to be implemented. The patterning occurs using a photolithography mask and chemical etching or another suitable etching or patterning process. With conductive layers 124 and 126 being formed of different materials, an etchant chemical that is selective for conductive layer 126 can be used.

In FIG. 3e, conductive layer 124 is etched to form a plurality of conductive vias 124a under contact pads 126a. In one embodiment, an etchant chemical that is selective for the material of conductive layer 124 is used, so that contact pads 126a operate as a mask for the etching process and another photolithographic mask is not needed. In another embodiment, conductive layers 124 and 126 are etched together in a single step. Portions of conductive layer 124 can remain to electrically connect conductive vias 124a to each other as desired to implement the intended electrical functionality, with or without overlying portions of conductive layer 126 being left as conductive traces. Contact pads 126a and conductive vias 124a can be formed by selective plating of their respective conductive layers rather than forming the conductive layers covering carrier 120 and then patterning.

In FIG. 3f, electrical components 130, and any other desired electrical components, are disposed on contact pads 126a. FIG. 3g illustrates a plan view of components 130 mounted. Electrical components 130 are positioned over carrier 120 using a pick and place operation. For example, electrical components 130 can be discrete electrical devices, such as diodes, transistors, resistors, capacitors, and inductors. Electrical components 130 can include any other desired semiconductor die, semiconductor packages, surface mount devices, RF components, or discrete electrical devices. Any of the electrical components 130 can also have integrated passive devices (IPDs) formed thereon.

Electrical components 130 are brought into contact with contact pads 126a. Terminals 132 of electrical components 130 are electrically and mechanically connected to contact pads 126a using solder or conductive paste 134. Solder paste 134 can be reflowed to improve mechanical attachment. The thicknesses of conductive layers 124 and 126 can be tuned, together with the amount and type of solder used for solder paste 134, to optimize warpage for the passive modules being formed and the eventual packages to be formed with the modules.

In one embodiment, a vertical thickness of contact pads 126a is in the range of 1-8 μm and a vertical thickness of conductive vias 124b is in the range of 2-150 μm. Solder paste 134 adds a stand-off in the range of 5-150 μm. The thickness of solder paste 134 can be used to adjust warpage of module 150 and the final package made therewith. Adding a nickel contact pad 126a between conductive via 124b and solder paste 134 helps to suppress Kirkendall voids by reducing wetting of the copper sidewalls of the conductive vias with solder.

In FIG. 3h, encapsulant or molding compound 140 is deposited over and around carrier 120 and electrical components 130 using a paste printing, compressive molding, transfer molding, liquid encapsulant molding, vacuum lamination, spin coating, or another suitable applicator to form a panel 142. Encapsulant 140 can be liquid or granular polymer composite material, such as epoxy resin, epoxy acrylate, or polymer, with or without an added filler. Encapsulant 140 is non-conductive, provides structural support, and environmentally protects electrical components 130 from external elements and contaminants. Encapsulant 140 completely covers tops, bottoms, and all sides of electrical components 130. In one embodiment, encapsulant 140 extends over the tops of components 130 by 10-500 μm to protect the components and adjust warpage.

Deposition of encapsulant 140 is less likely to result in flying components compared to the prior art for a number of reasons. Because smaller electrical components 130 are encapsulated in their own process, the specific molding material and method can be customized to reduce the likelihood of flying components. Moreover, electrical components 130 are attached to carrier 120 by two deposited conductive layers and solder paste 134 that has a stronger bond than simply picking and placing the components onto a carrier. Separately encapsulating electrical components 130 also reduces the financial impact of flying components, because only the individual modules need to be discarded and not entire packages. The coefficient of thermal expansion (CTE) and modulus of encapsulant 140 can be selected to properly tune panel 142, and the final packages to be formed with the resulting modules, for warpage.

In FIG. 3i, panel 142 is removed from carrier 120 and flipped so that the now-exposed conductive vias 124a are exposed. Conductive vias 124a are optionally etched to form conductive vias 124b recessed below surface 144 of encapsulant 140. Conductive vias 124b are recessed up to 15 micrometers (μm) below surface 144 in one embodiment. Alternatively, encapsulant 140 can be etched to leave conductive vias 124a extending over surface 144. In some embodiments, a build-up interconnect structure, including one or more conductive RDL layers interleaved with insulating or passivation layers, are formed over surface 144 to electrically interconnect electrical components 130 as desired.

In FIG. 3j, panel 142 is cut through saw streets 123 with a laser cutting tool 148, water cutting tool, saw blade, or other suitable means, to form individual passive modules 150 as shown in FIG. 3k. Passive modules 150 include a plurality of electrical components 130 packaged and usable together to form a larger fan-out package. Pre-assembled passive modules 150 are less likely to move during manufacture of the larger package compared to the plurality of individual electrical components 130 being used separately. An optional shielding layer is formed over the top and side surfaces of encapsulant 140 in some embodiments.

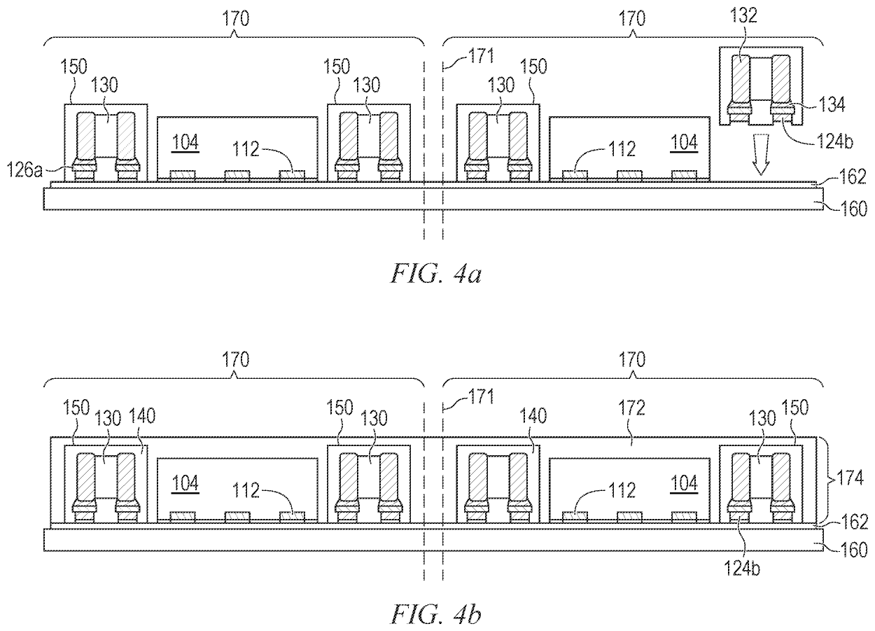

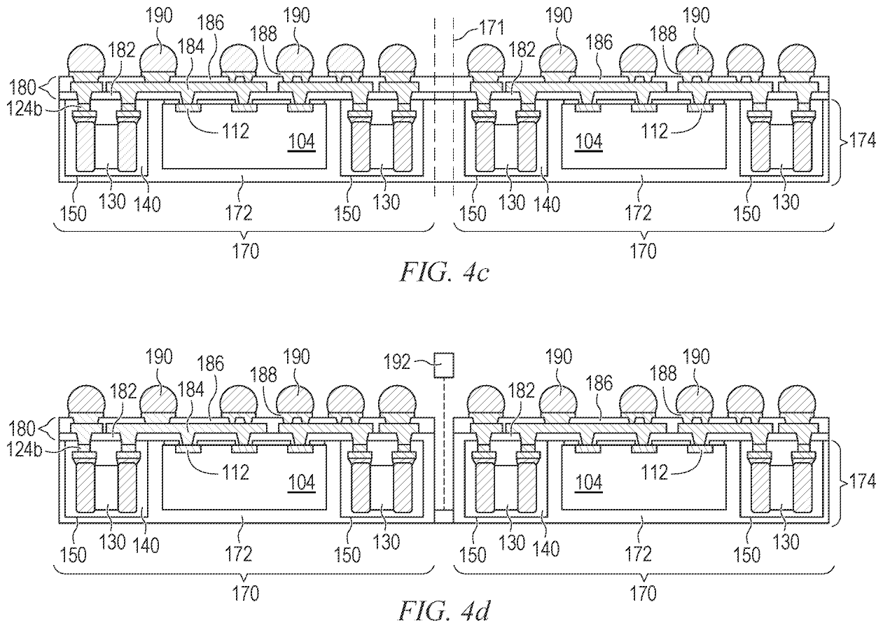

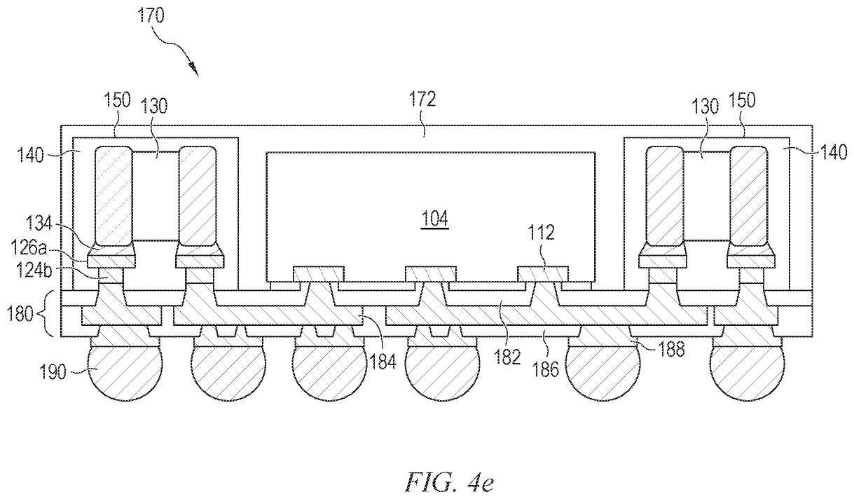

FIGS. 4a-4e illustrate formation of fan-out semiconductor packages 170 with modules 150. In FIG. 4a, semiconductor die 104 from FIG. 2c and modules 150 from FIG. 3k are disposed over a carrier 160 with interface layer 162. Carrier 160 and interface layer 162 are similar to or the same as described above for carrier 120. Semiconductor die 104 are disposed with contact pads 112 oriented toward carrier 160. Modules 150 are oriented with conductive vias 124b oriented toward carrier 160.

While two semiconductor packages 170 are being formed in the illustrations, separated by saw street 171, tens, hundreds, or more units can be formed together on a single carrier. Each package 170 includes two modules 150. The two modules can have the same or different components 130 depending on what is desired to support the functionality of semiconductor die 104. In some embodiments, modules 150 are formed doubled-up or mirrored so that a single module 150 can extend across saw street 171 and be used for two different semiconductor packages 170.

In FIG. 4b, encapsulant 172 is deposited over carrier 160, modules 150, and semiconductor die 104 to form a panel 174. Encapsulant 172 can be deposited using any of the methods and materials described above for encapsulant 140. The actual materials selected for encapsulant 140 and encapsulant 172 can be different, and each customized to control the warpage of packages 170 or panel 174. Having electrical components 130 in pre-assembled modules 150 reduces manufacturing defects because modules 150 are less likely to be moved by the molding process compared to individual electrical components 130. In embodiments where conductive vias 124a remain extending proud of surface 144 of encapsulant 140, some encapsulant 172 flows under modules 150 and helps keep modules 150 within the encapsulant over the lifetime of the package.

In FIG. 4c, panel 174 is removed from carrier 160 and flipped so that active surfaces 110 of semiconductor die 104 are exposed. A build-up interconnect structure 180 is formed over panel 174 as follows. First, an insulating layer 182 is formed over active surfaces 110, modules 150, and encapsulant 172. Insulating layer 182 contains one or more layers of SiO2, Si3N4, SiON, Ta2O5, Al2O3, or other material having similar insulating and structural properties. A portion of insulating layer 182 is removed by LDA, etching, or other suitable process to expose conductive vias 124b and contact pads 112 for subsequent electrical interconnect.

An electrically conductive layer 184 is formed over insulating layer 182 using PVD, CVD, electrolytic plating, electroless plating, or other suitable metal deposition process. Conductive layer 184 contains one or more layers of Al, Cu, Sn, Ni, Au, Ag, or other suitable electrically conductive material. Conductive layer 184 extends through openings in insulating layer 182 to electrically connect to semiconductor die 104 through contact pads 112 and electrical components 130 through conductive vias 124b, contact pads 126a, and solder paste 134. Portions of conductive layer 184 can be electrically common or electrically isolated depending on the design and function of semiconductor die 104. Conductive layer 184 operate as an RDL to fan-out and extend electrical connection from the semiconductor die.

A second insulating layer 186 is formed over conductive layer 184. In some embodiments, insulating layer 186 is similar to insulating layer 182, and successive insulating and redistribution layers are formed indefinitely over panel 174 as necessary to implement the desired signal routing. Insulating layer 186 is a passivation layer in other embodiments. Openings are formed through insulating layer 186 to expose portions of conductive layer 184 for electrical interconnect.

Contact pads 188 are formed over insulating layer 186 and extending into the openings of the insulating layer to physically and electrically contact conductive layer 184. Contact pads 188 are formed in a similar way and of similar materials as described above for the underlying conductive layers. Each contact pad 188 may have multiple small vias through insulating layer 186 to contact conductive layer 184, multiple slot vias, or a single larger via.

An electrically conductive bump material is deposited over contact pads 188 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to contact pads 188 using a suitable attachment or bonding process. In one embodiment, the bump material is reflowed by heating the material above its melting point to form balls or bumps 190. In one embodiment, bump 190 is formed over an under-bump metallization (UBM) having a wetting layer, barrier layer, and adhesion layer. The adhesion or seed layer is formed of Ti/Cu, Titanium Tungsten (TiW)/Cu, or a coupling agent/Cu in some embodiments. Bump 190 can also be compression bonded or thermocompression bonded to contact pads 188. Bump 190 represents one type of interconnect structure that can be formed over contact pads 188. The interconnect structure can also use bond wires, conductive paste, stud bumps, micro bumps, or another type of electrical interconnect. Contact pads 188 may also remain as a land-grid array without an additional interconnect structure being formed.

FIG. 4d illustrates singulating panel 174 into a plurality of semiconductor packages 170 using a laser cutting tool 192, water cutting tool, saw blade, or another suitable tool. FIG. 4e shows a completed package 170. Components 130 and semiconductor die 104 are connected to each other and bumps 190 by conductive layer 184. Using passive modules 150 that are pre-assembled with a separate encapsulant 140 reduces manufacturing defects by holding components 130 together during deposition of encapsulant 172. Using two separate encapsulants also allows the materials, CTE, and modulus to be tuned separately for components 130 and package 170 as a whole, giving better control over the warpage of panel 142, modules 150, panel 174, and packages 170. An optional shielding layer is formed over the top and side surfaces of encapsulant 172 in some embodiments. Any of the below embodiments can also have a shielding layer formed over the final package configuration, over one or more of the passive modules, or both.

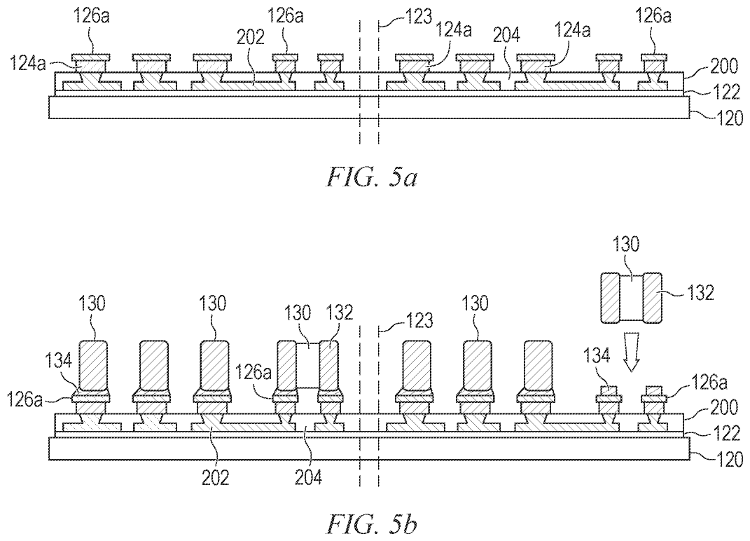

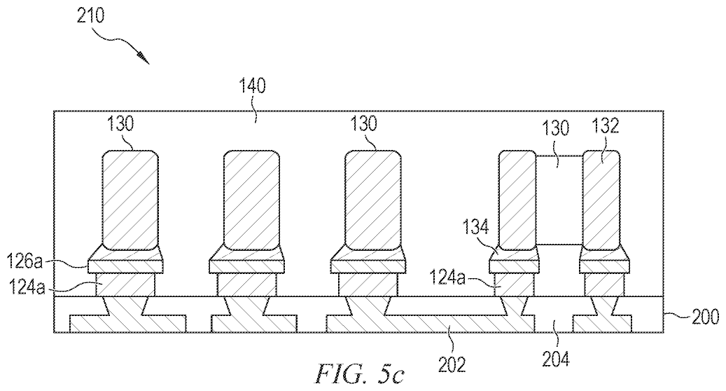

FIGS. 5a-5c illustrate forming a pre-assembled passive module that incorporates an interconnect substrate 200 into the module. FIG. 5a illustrates a cross-section of substrate 200, including conductive layers 202 and insulating layers 204, disposed on carrier 120. While only a single substrate 200 suitable to form two passive modules is shown, hundreds or thousands of units are commonly manufactured and processed as part of a single substrate before being singulated from each other, using the same steps described herein performed en masse. A separate substrate 200 could also be used for each unit being manufactured, the substrate being singulated before the steps shown in FIGS. 5a-5c and a plurality of individual substrates being placed on carrier 120 for processing.

Conductive layers 202 can be one or more layers of Al, Cu, Sn, Ni, Au, Ag, or other suitable electrically conductive material. Conductive layers 202 can be formed using PVD, CVD, electrolytic plating, electroless plating, or another suitable metal deposition process. Conductive layers 202 provide horizontal electrical interconnect across substrate 200 and vertical electrical interconnect between surfaces and layers of the substrate. Portions of conductive layers 202 can be electrically common or electrically isolated depending on the design and function of the package being formed. Conductive layers 202 may operate as redistribution layers for the pre-assembled passive module being formed.

Insulating layers 204 contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers 204 can be formed using PVD, CVD, printing, lamination, spin coating, spray coating, sintering, thermal oxidation, or another suitable process. Insulating layers 204 provide isolation between conductive layers 202. Any number of conductive layers 202 and insulating layers 204 can be interleaved over each other to form substrate 200. Any other suitable type of package substrate or leadframe is used for substrate 200 in other embodiments.

Conductive vias 124a and contact pads 126a are formed in FIG. 5a as shown above in FIGS. 3a-3e, except that in FIG. 5a the conductive structures are formed on substrate 200 instead of directly on carrier 120. Electrical components 130 are mounted in FIG. 5b as shown above in FIG. 3f. Encapsulation and singulation occur as shown above in FIGS. 3h and 3j to finish passive module 210 in FIG. 5c. Module 210 is similar to module 150 above but has an integrated substrate 200 for signal routing. In one embodiment, substrate 200 is a laminate or PCB substrate with a thickness in the range of 50-300 μm with prepreg/build-up dielectric or core dielectric CTE in the range of 3-30 ppm/° C. Packages 170 from FIGS. 4a-4e can be formed with modules 210, or any disclosed module, used instead of or in addition to modules 150.

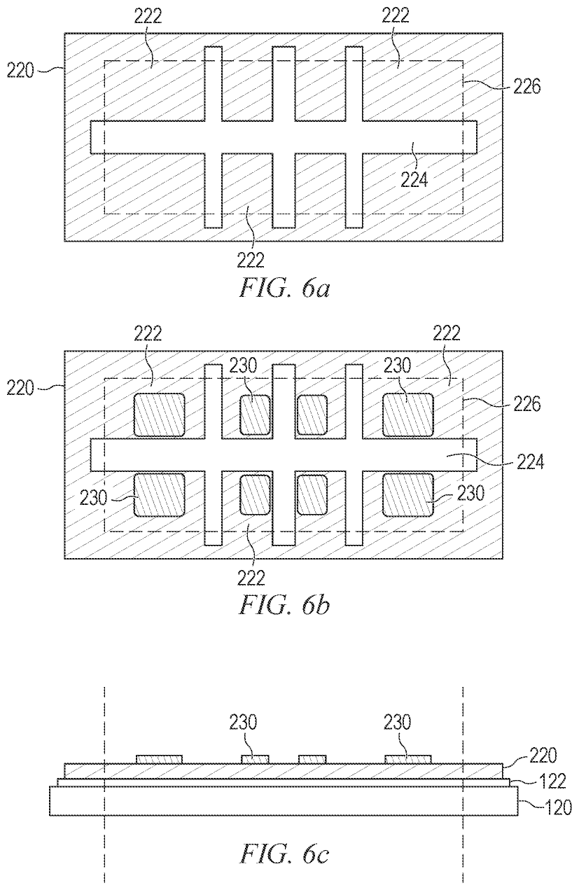

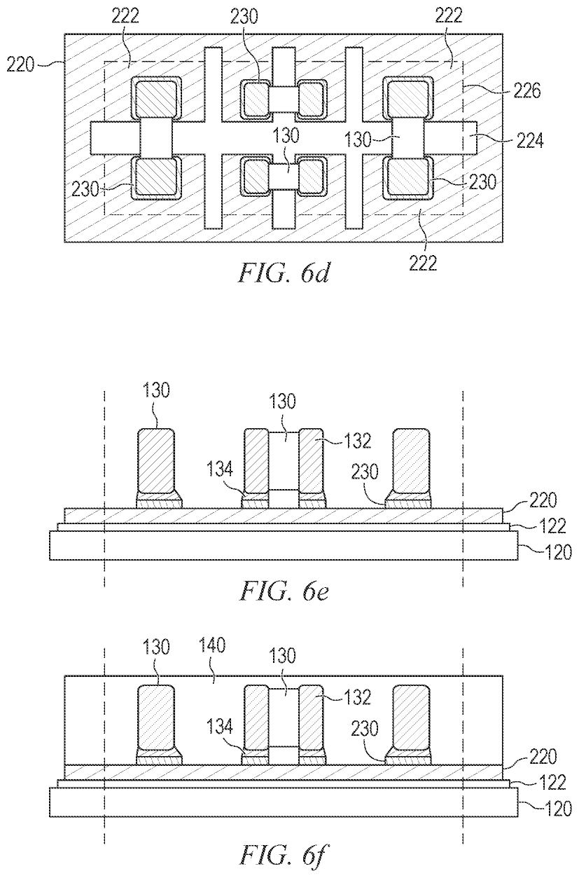

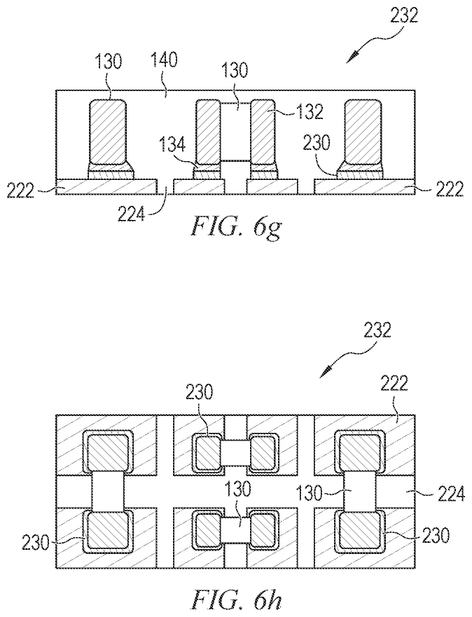

FIGS. 6a-6h illustrate forming a pre-assembled passive module with leadframe technology. FIG. 6a shows a plan view of leadframe 220 with a plurality of contacts 222. An opening 224 through leadframe 220 extends laterally between each contact 222 and across device boundary 226 into the saw street between units so that the contacts 222 are electrically separated from each other when the module is eventually singulated. While a leadframe for a single unit is illustrated, the leadframe can be tessellated large enough for tens, hundreds, or more units to be formed on a single leadframe. Any form and type of leadframe can be used.

Leadframe 220 is formed from a sheet of conductive material, commonly copper. Opening 224 is formed through the conductive material using laser cutting, chemical etching, mechanical punching, or another suitable means. In some embodiments, a wetting layer is plated onto the copper at any suitable manufacturing step.

In FIGS. 6b and 6c, contact pads 230 are formed with one contact pad on each of the leadframe contacts 222. FIG. 6b shows a plan view while FIG. 6c shows a cross-sectional view. Contact pads 230 are analogous to contact pads 126a above and formed to similar specifications. In one embodiment, leadframe 220 is a copper leadframe with a thickness between 15-150 μm and contact pads 230 are a 1-8 μm thick layer of nickel or electroless nickel electroless palladium immersion gold (ENEPIG).

In FIGS. 6d and 6e, electrical components 130 are disposed on contact pads 230 with solder paste 134 between the contact pads and terminals 132. FIG. 6d shows a plan view while FIG. 6e shows a cross-sectional view. Encapsulant 140 is deposited over leadframe 220 and components 130 in FIG. 6f. Encapsulant 140 extends down into opening 224.

FIGS. 6g and 6h show a completed passive module 232 after singulation. FIG. 6g shows a cross-sectional view while FIG. 6h shows a plan view. Leadframe 220 is cut at device boundary 226, which removes the direct electrical connection between each contact 222 that had been provided by the frame of leadframe 220. Module 232 is similar to module 150, but with conductive vias 124b replaced by contacts 222. Contacts 222 are formed to a similar thickness as conductive vias 124b, i.e., between 15-150 μm in one embodiment, but are wider, extending completely to the edge of module 232. Module 232 is usable instead of or in addition to module 150 in packages 170.

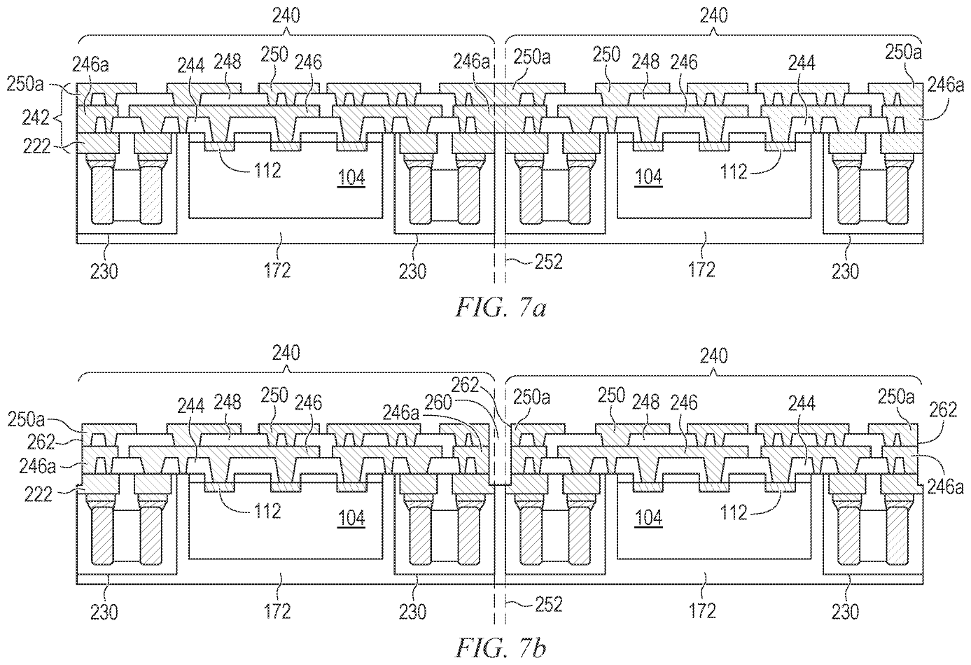

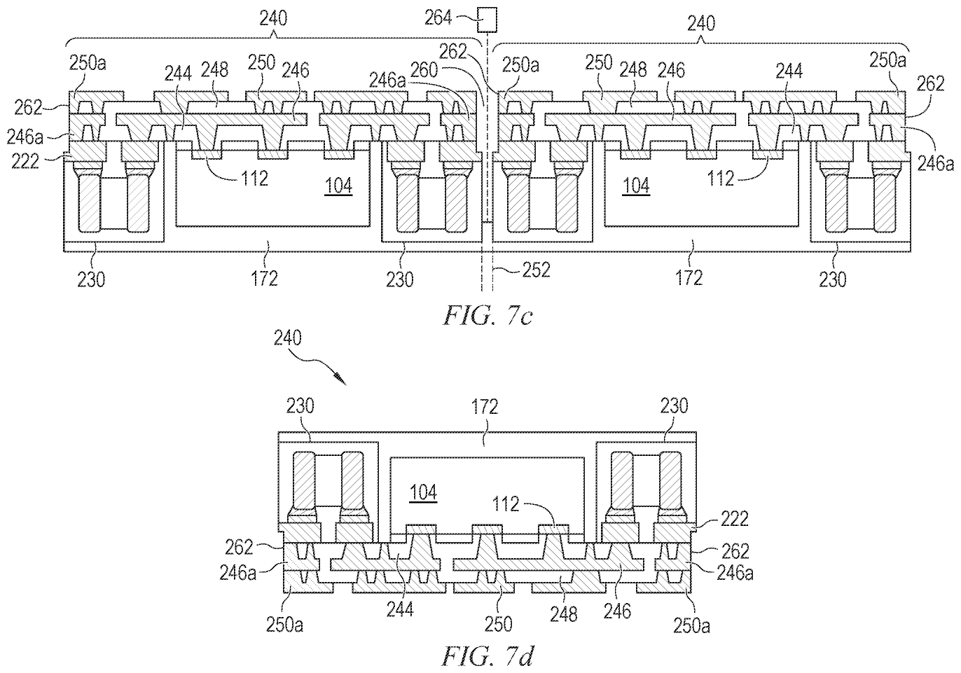

FIGS. 7a-7d illustrate forming fan-out semiconductor packages 240 with wettable flanks. FIG. 7a shows a panel of devices formed similar to panel 174 in FIG. 4b. Passive module 232 with leadframe contacts 222 is used instead of module 150. Leadframe contacts 222 extending completely to the edge of modules 230 helps increase the vertical extent of stacked conductive material available for a wettable flank, but a similar wettable flank concept can be accomplished with any of the other disclosed passive module embodiments.

A build-up interconnect structure 242 is formed over the panel of devices in a similar manner to build-up interconnect structure 180. Insulating layer 244, conductive layer 246, insulating layer 248, and conductive layer 250 in build-up interconnect structure 242 are formed similarly to insulating layer 182, conductive layer 184, insulating layer 186, and contact pads 188, respectively. Solder bumps 190 are optionally formed on contact pads of conductive layer 250.

Conductive layer 246 is formed with a conductive via 246a at the outer edge of each package 240 over leadframe contacts 222. Conductive vias 246a each extends through an opening in insulating layer 244 to electrically connect to a contact 222 and also extends laterally to saw street 252 at the edge of a package 240. Adjacent vias 246a of different packages are optionally continuous across saw street 252.

Conductive layer 250 is similarly formed with a conductive via 250a at the outer edge of each package 240 over leadframe contacts 222 and conductive vias 246a. Conductive vias 250a each extends through an opening in insulating layer 248 to physically and electrically connect to a conductive via 246a. Contacts 222, conductive vias 246a, and conductive vias 250a form a stack of conductive material at the edge of packages 240 wherever there is a contact 222 at the edge of the packages.

In FIG. 7b, trenches 260 are formed in saw-street 252 through build-up interconnect structure 242 and into contacts 222. Trenches 260 are formed by a saw blade or other suitable means. Trenches 260 form wettable flanks 262 by creating exposed side surfaces of conductive via 250a, conductive via 246a, and contacts 222. Wettable flanks 262 also include a horizontal surface of contacts 222 at the bottom of trenches 260.

In FIG. 7c, packages 240 are singulated from each other by cutting through saw streets 252 with a laser cutting tool 264 or other suitable means. Portions of the encapsulant of modules 230 may be removed during singulation in embodiments where modules 230 extend into saw street 252 or when the modules are formed double wide and shared between two adjacent units. In other embodiments, a portion of encapsulant 174 remains covering outer side surfaces of modules 230.

FIG. 7d shows a completed package 240. Wettable flanks 262 are exposed at a side surface of packages 240 and include coplanar surfaces of conductive vias 250a, conductive vias 246a, and contacts 222. Wettable flanks 262 are plated with a solder-wettable material in some embodiments. Wettable flanks 262 allow solder to reflow up a side surface of the package, creating a solder fillet that extends outside a footprint of the package for verification of proper installation of package 240.

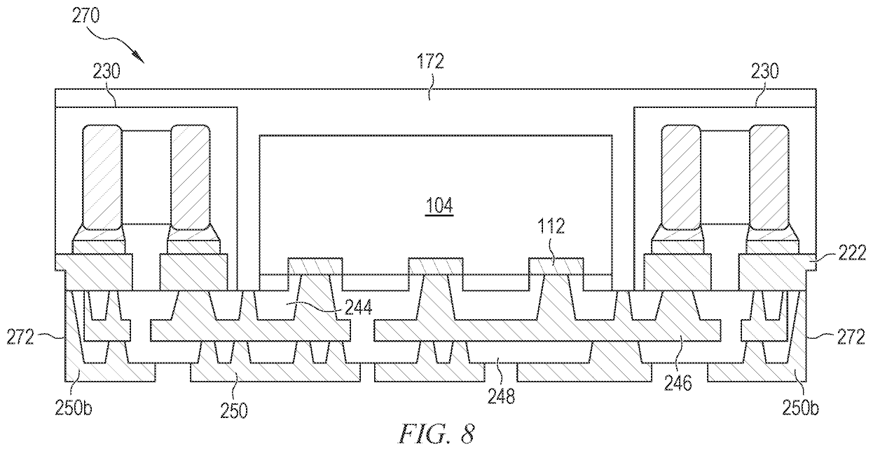

FIG. 8 shows an alternative embodiment as semiconductor package 270 with wettable flanks 272. Wettable flanks 272 are formed from conductive vias 250b of conductive layer 250, which extend completely through the build-up interconnect structure to physically and electrically contact leadframe contact pads 222. Besides conductive via 250b extending to contact 222, instead of an intervening conductive via of conductive layer 246, package 270 is formed similarly to package 240.

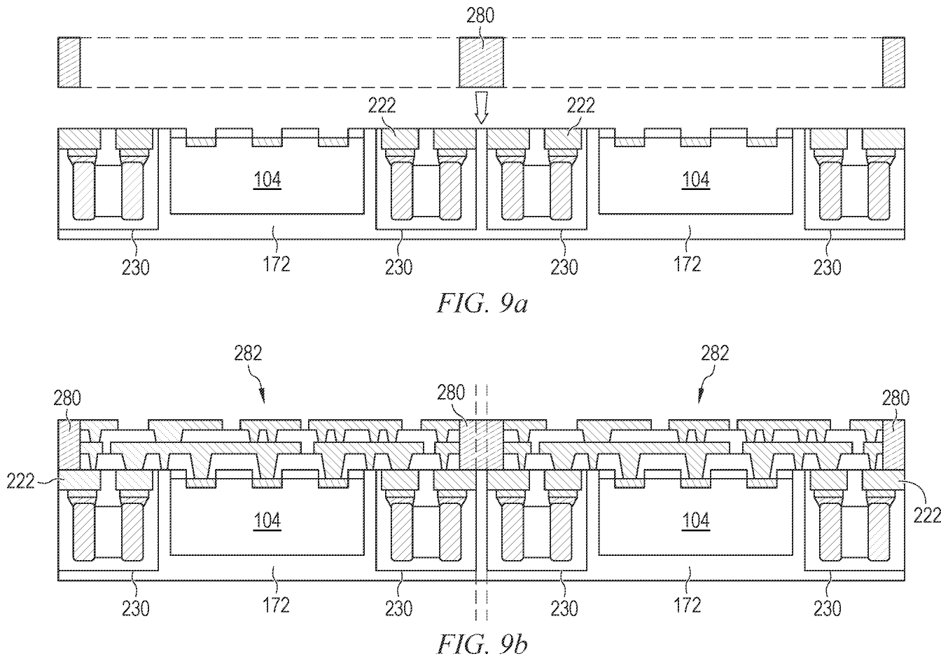

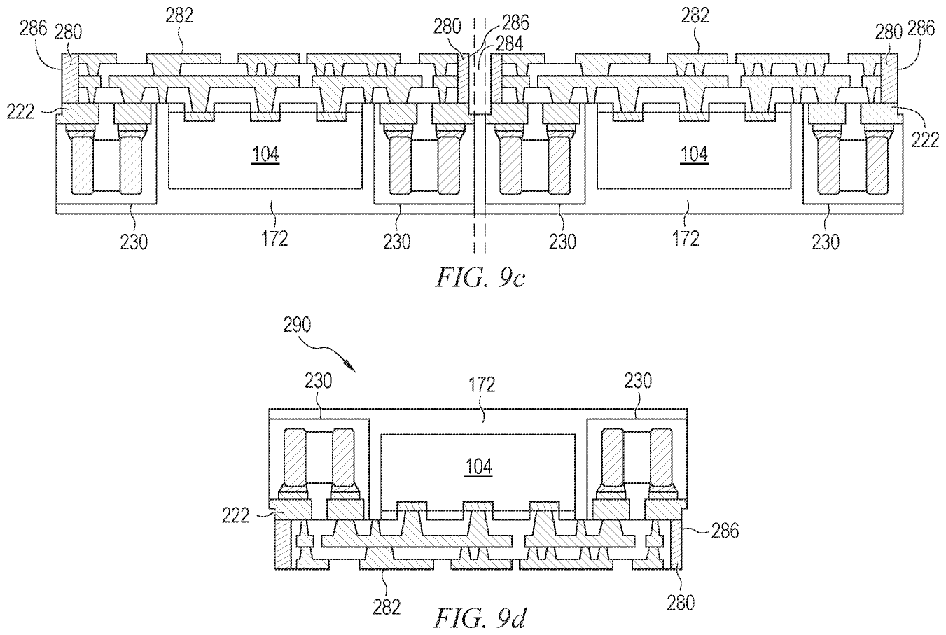

FIGS. 9a-9d illustrate an embodiment where wettable flanks are formed using leadframe technology. FIG. 9a shows a panel of devices with modules 230 as in FIG. 7a. Instead of forming wettable flanks as part of a build-up interconnect structure, a leadframe 280 is disposed over the panel of devices. Leadframe 280 includes a laterally thicker portion over each contact 222 and a thinner portion between contacts, so that the contacts are not electrically connected to each other by the leadframe after singulation. Leadframe 280 is disposed directly on and electrically connected to contacts 222. Leadframe 280 can be attached to contacts 222 using a layer of solder, thermocompression, or another suitable means.

In FIG. 9b, a build-up interconnect structure 282 is formed over semiconductor die 104 and modules 230 within leadframe 280. A trench 284 is formed into leadframe 280 in FIG. 9c to create wettable flanks 286 with exposed side surfaces of leadframe 280 and contacts 222 and a horizontal portion of contacts 222 in the bottom of the trenches. Trenches 284 completely remove leadframe 280 in areas without contacts 222 to electrically separate contacts 222 from each other. FIG. 9d shows a completed package 290 with wettable flanks 286 after singulation of the panel in FIG. 9c.

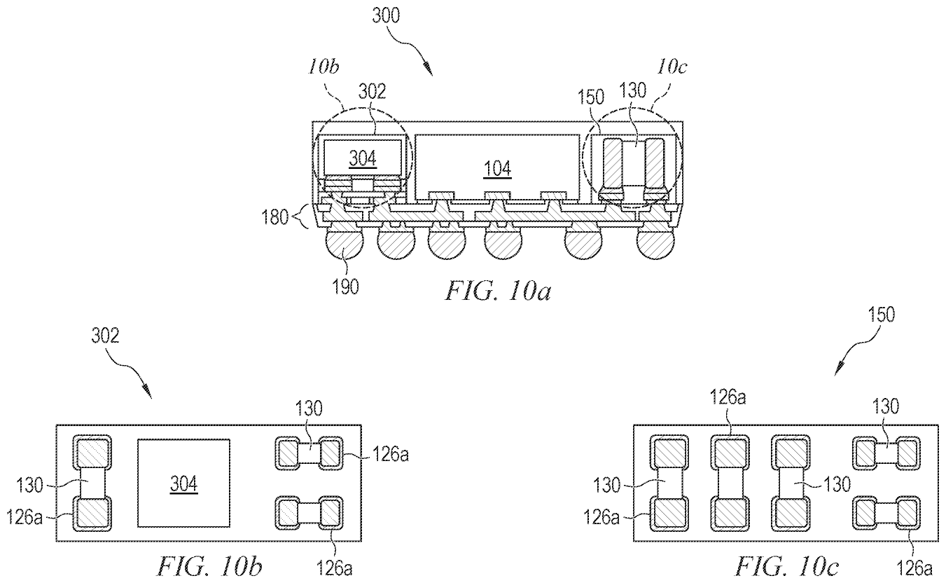

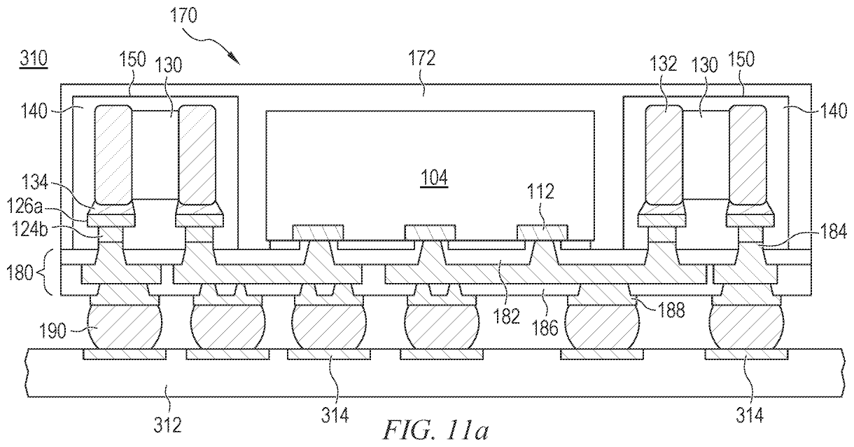

Packages can be formed with any mix of components within pre-assembled modules. Packages can be formed with multiple pre-assembled modules with different components. Any suitable components in any combination across any number of pre-assembled modules can be used in any disclosed pre-assembled passive module embodiment. FIGS. 10a-10c show just one possible combination for example. FIG. 10a shows package 300, which keeps module 150 as described and illustrated above. In addition, a second pre-assembled module 302 is disposed adjacent to semiconductor die 104 as part of package 300. FIG. 10b shows a plan view of module 302, while FIG. 10c shows a plan view of module 150.

Module 302 is formed in substantially the same manner as described above for any of the pre-assembled module embodiments. Instead of electrical components 130 being strictly passive components, a semiconductor die 304 is mounted onto contact pads 126a alongside the other electrical components. Semiconductor die 304 can include a discrete component, such as a diode or transistor. Semiconductor die 304 may also include a more complicated integrated circuit, such as a memory, processor, or amplifier.

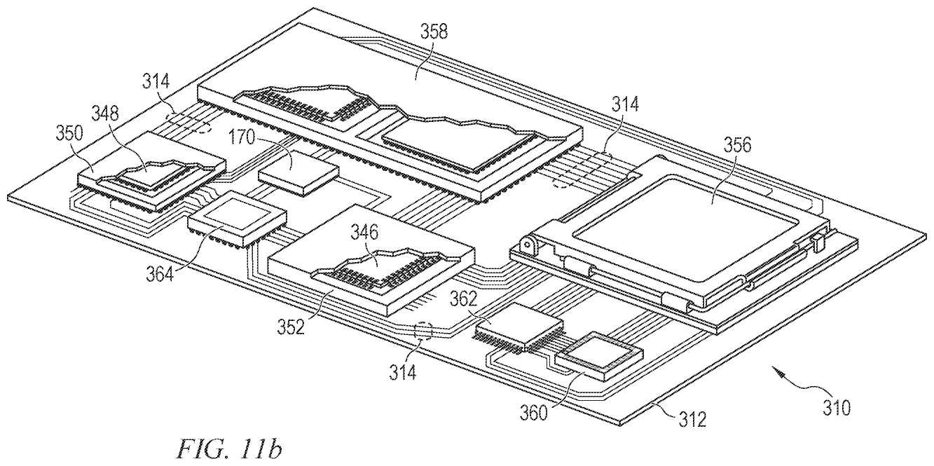

FIGS. 11a and 11b illustrate integrating the above-described semiconductor packages, e.g., semiconductor package 170, into a larger electronic device 310. FIG. 11a illustrates a partial cross-section of semiconductor package 170 mounted onto a printed circuit board (PCB) or other substrate 312 as part of electronic device 310. Bumps 190 are reflowed onto conductive layer 314 of PCB 312 to physically attach and electrically connect semiconductor package 170 to the PCB. In other embodiments, thermocompression or other suitable attachment and connection methods are used. In some embodiments, an adhesive or underfill layer is used between semiconductor package 170 and PCB 312. Semiconductor die 104 and electrical components 130 are electrically coupled to conductive layer 314 through bumps 190 and build-up interconnect structure 180.

FIG. 11b illustrates electronic device 310 including PCB 312 with a plurality of semiconductor packages mounted on a surface of the PCB, including semiconductor package 170. Electronic device 310 can have one type of semiconductor package, or multiple types of semiconductor packages, depending on the application. Electronic device 310 can be a stand-alone system that uses the semiconductor packages to perform one or more electrical functions. Alternatively, electronic device 310 can be a subcomponent of a larger system. For example, electronic device 310 can be part of a tablet computer, cellular phone, digital camera, communication system, or other electronic device. Electronic device 310 can also be a graphics card, network interface card, or another signal processing card that is inserted into a computer. The semiconductor packages can include microprocessors, memories, ASICs, logic circuits, analog circuits, RF circuits, discrete active or passive devices, or other semiconductor die or electrical components.

In FIG. 11b, PCB 312 provides a general substrate for structural support and electrical interconnection of the semiconductor packages mounted on the PCB. Conductive signal traces 314 are formed over a surface or within layers of PCB 312 using evaporation, electrolytic plating, electroless plating, screen printing, or other suitable metal deposition process. Signal traces 314 provide for electrical communication between the semiconductor packages, mounted components, and other external systems or components. Traces 314 also provide power and ground connections to the semiconductor packages as needed.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to PCB 312. In other embodiments, a semiconductor device may only have the first level packaging where the die is mechanically and electrically mounted directly to PCB 312.

For the purpose of illustration, several types of first level packaging, including bond wire package 346 and flipchip 348, are shown on PCB 312. Additionally, several types of second level packaging, including ball grid array (BGA) 350, bump chip carrier (BCC) 352, land grid array (LGA) 356, multi-chip module (MCM) 358, quad flat non-leaded package (QFN) 360, quad flat package 362, and embedded wafer level ball grid array (eWLB) 364 are shown mounted on PCB 312 along with semiconductor package 170. Conductive traces 314 electrically couple the various packages and components disposed on PCB 312 to semiconductor package 170, giving use of semiconductor die 104 with electrical components 130 to other components on the PCB.

Depending upon the system requirements, any combination of semiconductor packages, configured with any combination of first and second level packaging styles, as well as other electronic components, can be connected to PCB 312. In some embodiments, electronic device 310 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a plurality of electrical components;
depositing a first encapsulant over the plurality of electrical components to form a module;
disposing the module adjacent to a semiconductor die;
depositing a second encapsulant over the semiconductor die and module; and
forming a build-up interconnect structure over the second encapsulant, module, and semiconductor die.

2. The method of claim 1, wherein providing the plurality of electrical components includes:
providing a passive component; and
providing a second semiconductor die.

3. The method of claim 1, further including:
forming a first conductive layer;
forming a second conductive layer; and
disposing the electrical components over the first conductive layer and second conductive layer prior to depositing the first encapsulant.

4. The method of claim 1, further including disposing the electrical components over a leadframe prior to depositing the first encapsulant.

5. The method of claim 1, further including forming the build-up interconnect structure to include a wettable flank.

6. The method of claim 1, further including forming the module to include a redistribution layer.

7. A method of making a semiconductor device, comprising:
providing an electrical component;
depositing a first encapsulant over the electrical component to form a module;
disposing the module adjacent to a semiconductor die; and
depositing a second encapsulant over the semiconductor die and module.

8. The method of claim 7, further including:
providing a second semiconductor die; and
disposing the first encapsulant over the electrical component and second semiconductor die.

9. The method of claim 7, further including:
forming a first conductive layer;
forming a second conductive layer; and
disposing the electrical component over the first conductive layer and second conductive layer prior to depositing the first encapsulant.

10. The method of claim 7, further including disposing the electrical component over a leadframe prior to depositing the first encapsulant.

11. The method of claim 7, further including forming a build-up interconnect structure including a wettable flank over the second encapsulant, semiconductor die, and module.

12. The method of claim 7, further including forming the module to include a redistribution layer.

13. The method of claim 7, further including forming a build-up interconnect structure over the module prior to depositing the second encapsulant.

14. A semiconductor device, comprising:
a plurality of electrical components;
a first encapsulant deposited over the plurality of electrical components to form a module;
a semiconductor die disposed adjacent to the module;
a second encapsulant deposited over the semiconductor die and module; and
a build-up interconnect structure formed over the second encapsulant, module, and semiconductor die.

15. The semiconductor device of claim 14, wherein the plurality of electrical components includes a passive component and a second semiconductor die.

16. The semiconductor device of claim 14, further including:
a contact pad; and
a conductive via, wherein the contact pad and conductive via are stacked between the plurality of electrical components and build-up interconnect structure within the first encapsulant.

17. The semiconductor device of claim 14, further including a leadframe disposed between the electrical components and build-up interconnect structure within the first encapsulant.

18. The semiconductor device of claim 14, wherein the build-up interconnect structure includes a wettable flank.

19. The semiconductor device of claim 14, wherein the module includes a redistribution layer.

20. A semiconductor device, comprising:
an electrical component;
a first encapsulant deposited over the electrical component;
a semiconductor die disposed adjacent to the electrical component outside the first encapsulant; and
a second encapsulant over the semiconductor die and first encapsulant.

21. The semiconductor device of claim 20, further including a second semiconductor die disposed within the first encapsulant.

22. The semiconductor device of claim 20, further including a first conductive layer and a second conductive layer disposed within the first encapsulant.

23. The semiconductor device of claim 20, further including a leadframe disposed within the first encapsulant.

24. The semiconductor device of claim 20, further including a build-up interconnect structure including a wettable flank formed over the first encapsulant, second encapsulant, semiconductor die, and electrical component.

25. The semiconductor device of claim 20, further including a build-up interconnect structure formed over the first encapsulant and electrical component and disposed within the second encapsulant.
